(19) United States
(12) Patent Application Publication
(10) Pub. No.: US 2025/0105175 A1
(43) Pub. Date: Mar. 27, 2025

(54) SEMICONDUCTOR CHIP INCLUDING CHIP GUARD STRUCTURE AND UPPER GUARD LINE DISPOSED SPACED APART FROM EACH OTHER

(71) Applicant: SK hynix Inc., Gyeonggi-do (KR)

(72) Inventor: Heon Yong CHANG, Gyeonggi-do (KR)

(21) Appl. No.: 18/424,871

(22) Filed: Jan. 29, 2024

(30) Foreign Application Priority Data
Sep. 26, 2023 (KR) 10-2023-0129837

(51) Int. Cl. H01L 23/58; H01L 23/00; H01L 23/50

(52) U.S. Cl. CPC H01L 23/585; H01L 23/50; H01L 24/05; H01L 2224/05024; H01L 2924/182

(57) ABSTRACT

A semiconductor chip according to an embodiment of the present disclosure includes a chip region and a chip sealing region disposed in a substrate, a circuit pattern structure disposed in the chip region, a chip guard structure disposed in the chip sealing region and surrounding the chip region, a voltage supply line disposed over the circuit pattern structure in the chip region and supplying a predetermined voltage to the circuit pattern structure, and an upper guard line disposed over the chip guard structure in the chip sealing region and electrically connected to the voltage supply line.

### CROSS-REFERENCE TO RELATED APPLICATIONS

The present application claims priority under 35 U.S.C. 119(a) to Korean Application No. 10-2023-0129837, filed on Sep. 26, 2023, which is incorporated herein by reference in its entirety.

### BACKGROUND

### 1. Technical Field

Embodiments of the present disclosure generally relate to a semiconductor chip including a protection pattern structure and, more particularly, to a semiconductor chip including a chip guard structure and an upper guard line that are disposed spaced apart from each other.

### 2. Related Art

A plurality of semiconductor chip regions separated from each other by a scribe lane region may be defined on a semiconductor wafer. After integrated circuits are fabricated in the plurality of semiconductor chip regions through a semiconductor fabricating process, the plurality of semiconductor chip regions may be separated into a plurality of semiconductor chips through a wafer sawing process.

Each of the plurality of semiconductor chip regions may be provided with a protection pattern structure, such as a guard ring, disposed in an outer region of each of the plurality of semiconductor chip regions for protecting the integrated circuit. The protection pattern structures may block moisture and prevent it from penetrating from the outside of the plurality of semiconductor chip regions into the plurality of semiconductor chip regions, thereby preventing the integrated circuits from being damaged by moisture.

### SUMMARY

A semiconductor chip according to an embodiment of the present disclosure may include a chip region and a chip sealing region disposed in a substrate, a circuit pattern structure disposed in the chip region, a chip guard structure disposed in the chip sealing region and surrounding the chip region, a voltage supply line disposed over the circuit pattern structure in the chip region and supplying a predetermined voltage to the circuit pattern structure, and an upper guard line disposed over the chip guard structure in the chip sealing region and electrically connected to the voltage supply line.

A semiconductor chip according to another embodiment of the present disclosure may include a substrate including a chip region and a chip sealing region located outside the chip region, a chip guard structure disposed in the chip sealing region which surrounds the chip region, a voltage supply line disposed in the chip region, and an upper guard line disposed in the chip sealing region spaced apart from the chip guard structure over the substrate. The upper guard line is electrically insulated from the chip guard structure, and electrically connected to the voltage supply line.

### BRIEF DESCRIPTION OF THE DRAWINGS

FIG. 1 is a plan view schematically illustrating a semiconductor wafer according to an embodiment of the present disclosure.

FIG. 2 is a plan view schematically illustrating a semiconductor chip according to an embodiment of the present disclosure.

FIG. 3 is a cross-sectional view of the semiconductor chip illustrated in FIG. 2 taken along a line I-I′.

FIG. 4 is a cross-sectional view of the semiconductor chip illustrated in FIG. 2 taken along a line II-II′.

FIG. 5 is a plan view schematically illustrating a semiconductor chip according to a first comparative example of the present disclosure.

FIG. 6 is a cross-sectional view of the semiconductor chip illustrated in FIG. 5 taken along a line III-III′.

FIG. 7 is a cross-sectional view illustrating a semiconductor chip according to a second comparative example of the present disclosure.

FIG. 8 is a plan view schematically illustrating a semiconductor chip according to another embodiment of the present disclosure.

FIG. 9 is a cross-sectional view of the semiconductor chip illustrated in FIG. 8 taken along a line IV-IV′.

FIG. 10 is a cross-sectional view of the semiconductor chip illustrated in FIG. 8 taken along a line V-V′.

FIG. 11 is a plan view schematically illustrating a semiconductor chip according to another embodiment of the present disclosure.

FIG. 12 is a cross-sectional view of the semiconductor chip illustrated in FIG. 11 taken along a line VI-VI′.

FIG. 13 is a cross-sectional view of the semiconductor chip illustrated in FIG. 11 taken along a line VII-VII′.

### DETAILED DESCRIPTION

The terms used in the description of this specification are terms selected in consideration of the functions in the presented embodiments, and the meaning of the terms may vary depending on the intention or custom of the user or operator in the technical field. The meaning of the terms used, if specifically defined in this specification, follows the defined definition, and if there is no specific definition, the meaning may be interpreted as generally recognized by those skilled in the art. In the description of the embodiments of the present disclosure, descriptions such as “first” and “second” are used to distinguish members, and are not used to limit the members themselves or to indicate a specific order. In addition, expression of a singular form of a word should be understood to include the plural forms of the word unless clearly used otherwise in the context.

The same reference signs may refer to the same elements throughout the specification. The same or similar reference signs may be described with reference to other drawings even if they are not mentioned or described in the corresponding drawings. Additionally, even if reference signs are not indicated, description may be made with reference to other drawings.

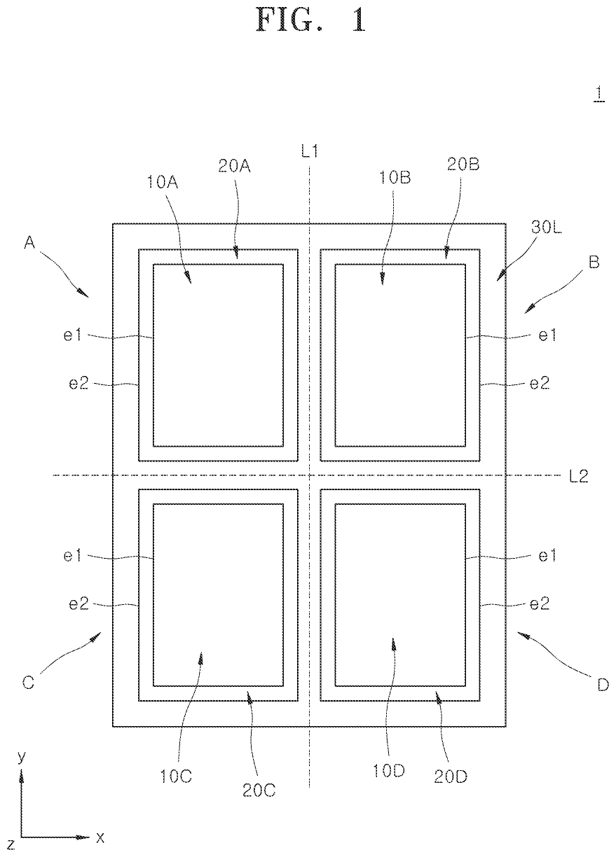

FIG. 1 is a plan view schematically illustrating a semiconductor wafer 1 according to an embodiment of the present disclosure. The semiconductor wafer 1 may include a plurality of chip regions, for example, chip regions 10A, 10B, 10C, and 10D, a plurality of chip sealing regions, for example, chip sealing regions 20A, 20B, 20C, and 20D, and a scribe lane region 30L surrounding the plurality of chip regions and the plurality of chip sealing regions. Each chip sealing region may surround a corresponding chip region of the plurality of chip regions 10A, 10B, 10C and 10D. For example, chip sealing region 20A may surround chip region 10A, chip sealing region 20B may surround chip region 10B, chip sealing region 20C may surround chip region 10C, and chip sealing region may surround chip region 10D. For the convenience of description, FIG. 1 illustrates first to fourth chip regions 10A, 10B, 10C, and 10D, first to fourth chip sealing regions 20A, 20B, 20C, and 20D, and the scribe lane region 30L. However, the inventive concept of the present disclosure is not necessarily limited thereto, and other numbers of chip regions and other numbers of chip sealing regions are possible.

Integrated circuits may be disposed in the plurality of chip regions 10A, 10B, 10C, and 10D to form semiconductor chips, respectively. The semiconductor chips formed in the plurality of chip regions 10A, 10B, 10C, and 10D may be substantially identical to each other. After formation of the integrated circuits are completed in the plurality of chip regions 10A, 10B, 10C, and 10D of the semiconductor wafer 1, the plurality of chip regions 10A, 10B, 10C, and 10D may be separated from each other, and a plurality of semiconductor chips A, B, C, and D may be provided.

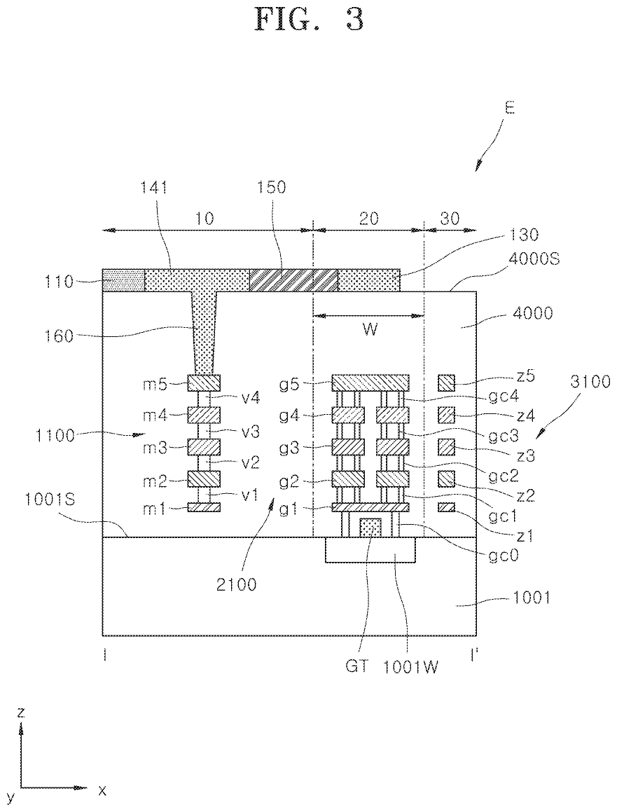

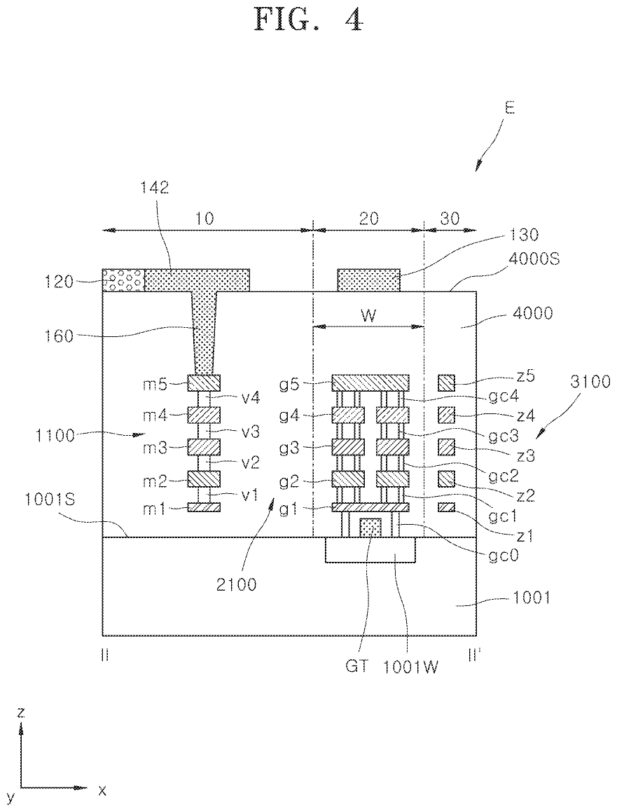

Referring to FIG. 1, in the scribe lane region 30L, the first to fourth chip regions 10A, 10B, 10C, and 10D may be separated from each other along a first cutting line L1 along the x-direction and a second cutting line L2 along the y-direction to fabricate the first to fourth semiconductor chips A, B, C, and D. The plurality of chip sealing regions 20A, 20B, 20C, and 20D may be located outside the plurality of chip regions 10A, 10B, 10C, and 10D, respectively. Each of the plurality of chip sealing regions 20A, 20B, 20C, and 20D may form a first boundary e1 with each of the plurality of chip regions 10A, 10C, 10C, and 10D, and form a second boundary e2 with the scribe lane region 30L. Each of the plurality of chip sealing regions 20A, 20B, 20C, and 20D may be disposed to surround a corresponding chip region among the plurality of chip regions 10A, 10B, 10C, and 10D. As will be described later with reference to FIGS. 3 and 4, a chip guard structure 2100 and an upper guard line 130 may be disposed in each of the plurality of chip sealing regions 20A, 20B, 20C, and 20D.

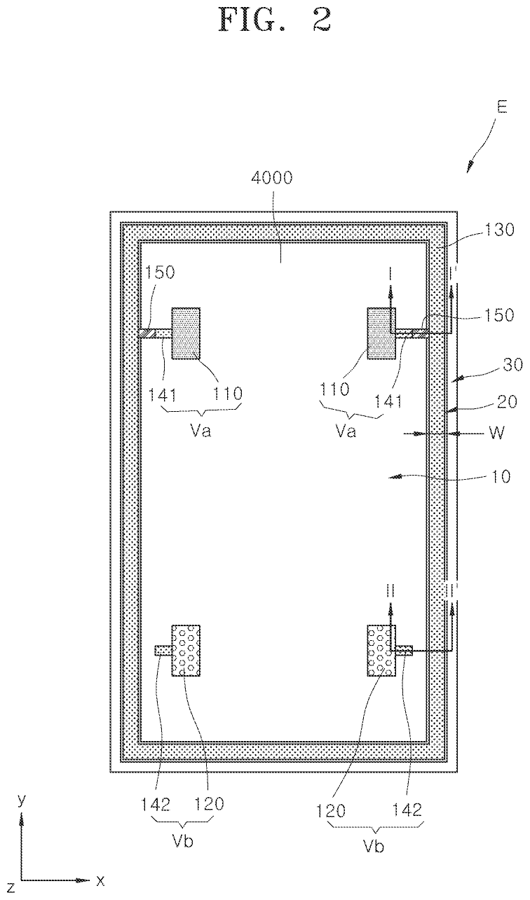

The scribe lane region 30L may be located outside the plurality of chip sealing regions 20A, 20B, 20C, and 20D. As will be described later with reference to FIGS. 2 to 4, various electrical test patterns or process monitoring patterns may be disposed in the scribe lane region 30L. However, the scribe lane region 30L may be divided along the first and second cutting lines L1 and L2, so that the plurality of semiconductor chips A, B, C, and D may be fabricated from the wafer 1.

FIG. 2 is a plan view schematically illustrating a semiconductor chip E according to an embodiment of the present disclosure. FIG. 3 is a cross-sectional view of the semiconductor chip E illustrated in FIG. 2 taken along a line I-I′. FIG. 4 is a cross-sectional view of the semiconductor chip E illustrated in FIG. 2 taken along a line II-II′. The semiconductor chip E may correspond to one of the plurality of semiconductor chips A, B, C, and D described with reference to FIG. 1.

Referring to FIGS. 2 to 4, the semiconductor chip E may include a chip region 10, a chip sealing region 20, and a scribe lane region 30 that are defined in a substrate 1001. The chip region 10 may correspond to one of the chip regions 10A, 10B, 10C, and 10D, and the chip sealing region 20 may correspond to one of the chip sealing regions 20A, 20B, 20C, and 20D, described with reference to FIG. 1. That is, the chip sealing region 20 may be disposed outside the chip region 10 to surround the chip region 10. In the plan view of FIG. 2, the chip sealing region 20 may be disposed in a band shape with a predetermined width W. The scribe lane region 30 may be a remaining portion included in the semiconductor chip E after the scribe lane region 30L described with reference to FIG. 1 is divided along the first and second cutting lines (L1 and L2 in FIG. 1). That is, the scribe lane region 30 may be disposed outside the chip sealing region 20.

Referring to FIG. 2, the semiconductor chip E may include voltage supply lines Va and Vb disposed in the chip region 10. The voltage supply lines Va and Vb may be disposed on a surface (4000S of FIG. 3) of an interlayer insulation layer 4000, and may provide predetermined voltages to a circuit pattern structure 1100 of the chip region 10 illustrated in FIGS. 3 and 4. FIGS. 2 to 4 illustrate voltage supply lines Va and Vb in pairs, but this is only an example and the embodiments of the present disclosure are not limited thereto.

The voltage supply lines Va and Vb may include power pads 110 and 120, respectively. The power pad 110 may be a ground pad 110. The power pad 120 may be an operation voltage pad 120. The ground and operation pads 110 and 120 may receive the predetermined voltage from an electronic device disposed outside the semiconductor chip E, and redistribution layers 141 and 142 extending from the corresponding power pads 110 and 120, respectively. In the illustrated embodiment, the voltage supply lines Va and Vb include a ground voltage supply line Va and an operation voltage supply line Vb that are electrically separated from each other. The ground voltage supply line Va may include the ground pad 110 that receives a ground voltage from the electronic device, and the first redistribution layer 141 extending from the ground pad 110 in a lateral direction (e.g., the x-direction). The operation voltage supply line Vb may include the operation voltage pad 120 that receives the operation voltage from the electronic device, and the second redistribution layer 142 extending from the operation voltage pad 120 in the lateral direction (e.g., the x-direction).

Referring again to FIG. 2, the semiconductor chip E may further include an upper guard line 130 disposed in the chip sealing region 20. The upper guard line 130 may surround the chip region 10. The upper guard line 130 may form or include a barrier structure that blocks moisture and prevents it from entering the chip region 10 from the outside.

In an embodiment, the upper guard line 130 may be disposed on substantially the same plane as the voltage supply lines Va and Vb. As an example, the upper guard line 130 may be disposed on the surface 4000S of the interlayer insulation layer 4000. In an embodiment, the upper guard line 130 and the voltage supply lines Va and Vb may include substantially the same conductive material. As an example, the upper guard line 130 and the voltage supply lines Va and Vb may include aluminum (Al).

In an embodiment, the upper guard line 130 may be electrically connected to the ground voltage supply line Va. Accordingly, the upper guard line 130 may maintain an electrical ground state within the semiconductor chip E. The upper guard line 130 may be connected to the ground voltage supply line Va through conductive connection pattern 150. The conductive connection pattern 150 may be disposed on substantially the same plane as the upper guard line 130, the ground pad 110, and the first redistribution layer 141. As an example, the conductive connection pattern 150 may be disposed on the surface 4000S of the interlayer insulation layer 4000. The upper guard line 130, the ground pad 110, the first redistribution layer 141, and the conductive connection pattern 150 may include substantially the same material. As an example, the conductive connection pattern 150 may include aluminum (Al). In an embodiment, the upper guard line 130 may be electrically insulated from the operation voltage supply line Vb. The upper guard line 130 may be disposed spaced apart from the operation voltage pad 120 and the second redistribution layer 142 on the surface (4000S of FIG. 3) of the interlayer insulation layer 4000.

Referring to FIGS. 3 and 4, the circuit pattern structure 1100 may be disposed in the chip region 10 and include a plurality of circuit pattern layers m1, m2, m3, m4, and m5 spaced apart from each other. The plurality of circuit pattern layers m1, m2, m3, m4, and m5 may be arranged in a direction perpendicular or substantially perpendicular to a top surface 1001S of the substrate 1001 (e.g., z-direction). A plurality of interlayer vias v1, v2, v3, and v4 may electrically connect the plurality of circuit pattern layers m1, m2, m3, m4, and m5 to each other. Each of the plurality of circuit pattern layers m1, m2, m3, m4, and m5 and each of the plurality of interlayer vias v1, v2, v3, and v4 may include, for example, tungsten (W), tungsten nitride, titanium (Ti), titanium nitride, aluminum (Al), copper (Cu), or any combination of two or more thereof.

The circuit pattern structure 1100 may be an electrical wiring connected to an integrated circuit that drives the semiconductor chip E. FIGS. 3 and 4 illustrate the first to fifth circuit pattern layers m1, m2, m3, m4, and m5 and the first to fourth interlayer vias v1, v2, v3, and v4 as examples of the plurality of circuit pattern layers m1, m2, m3, m4, and m5 and the plurality of interlayer vias v1, v2, v3, and v4, but the embodiments of the present disclosure are not necessarily limited thereto, and various other numbers of circuit pattern layers and interlayer vias are possible.

A ground line connection via 160 may be disposed to connect a top layer (i.e., the fifth circuit pattern layer m5) of the circuit pattern structure 1100 to the first redistribution layer 141. The ground line connection via 160 may electrically connect the ground voltage supply line Va to the circuit pattern structure 1100. Accordingly, the circuit pattern structure 1100 may maintain a ground state within the semiconductor chip E.

Referring to FIGS. 3 and 4, a chip guard structure 2100 may be disposed in the chip sealing region 20. The chip guard structure 2100 may be disposed to surround the chip region 10 over the substrate 1001. That is, the chip guard structure 2100 may be disposed around the chip region 10 in a fence shape. As an example, the chip guard structure 2100 may include a guard ring.

The chip guard structure 2100 may include a plurality of guard metal layers g1, g2, g3, g4, and g5 disposed over the substrate 1001 and spaced apart from each other in a direction perpendicular or substantially perpendicular to the surface of the substrate 1001. The chip guard structure 2100 may further include a plurality of intermetallic contact layers gc1, gc2, gc3, and gc4 connecting the plurality of guard metal layers g1, g2, g3, g4, and g5 to each other, and a lower contact layer gc0 connecting a bottom guard metal layer g1 among the plurality of guard metal layers g1, g2, g3, g4, and g5 to a ground well 1001W of the substrate 1001. In some embodiments, the chip guard structure 2100 may include a gate structure GT. The gate structure GT may include a gate dielectric layer (not illustrated) and a gate electrode layer (not illustrated) sequentially disposed over the substrate 1001.

Each of the plurality of guard metal layers g1, g2, g3, g4, and g5, each of the plurality of intermetallic contact layers gc1, gc2, gc3, and gc4, and the lower contact layer gc0 may include, for example, tungsten (W), tungsten nitride, titanium (Ti), titanium nitride, aluminum (Al), copper (Cu), or any combination of two or more thereof.

FIGS. 3 and 4 illustrate the first to fifth guard metal layers g1, g2, g3, g4, and g5 and the first to fourth intermetallic contact layers gc1, gc2, gc3, and gc4 as the plurality of guard metal layers g1, g2, g3, g4, and g5 and the plurality of intermetallic contact layers gc1, gc2, gc3, and gc4, respectively, but the embodiments of the present disclosure are not necessarily limited thereto, and various numbers of guard metal layers and various numbers of intermetallic contact layers are possible.

The ground well 1001W of the substrate 1001 may receive the ground voltage through a ground contact (not illustrated) connected to the ground well 1001W. The ground contact (not illustrated) may receive the ground voltage from the external device through various wirings inside the semiconductor chip E. The ground well 1001W may maintain a ground state within the semiconductor chip E. In an embodiment, when the substrate 1001 is a p-type doped substrate, the ground well 1001W may be a p-well doped at a higher concentration than the substrate 1001.

The chip guard structure 2100 may serve as a barrier structure that blocks and prevents external moisture from penetrating into the integrated circuit (e.g., the circuit pattern structure 1100) of the chip region 10. The chip guard structure 2100 may be electrically connected to the ground well 1001W of the substrate 1001. The chip guard structure 2100 may maintain an electrical ground state within the semiconductor chip E.

Referring to FIGS. 3 and 4, in the chip sealing region 20 having a predetermined width W, the upper guard line 130 may be disposed spaced apart from the chip guard structure 2100 in an upper direction of the chip guard structure 2100. The upper guard line 130 may be physically separated from the chip guard structure 2100. Additionally, the upper guard line 130 may be disposed to overlap the chip guard structure 2100 in a direction (i.e., z-direction) perpendicular or substantially perpendicular to the surface 1001W of the substrate 1001.

In an embodiment, over the substrate 1001, a conductive connection means connecting the upper guard line 130 to the chip guard structure 2100 may not be disposed in the interlayer insulation layer 4000 between the upper guard line 130 and the chip guard structure 2100. The conductive connection means may include, for example, a contact pattern, a via, etc. In this specification, the interlayer insulation layer 4000 may be a single layer or a structure in which a plurality of insulation layers are sequentially stacked.

Referring to FIG. 3, the conductive connection pattern 150 may be disposed across the chip region 10 and the chip sealing region 20. The conductive connection pattern 150 may connect the first redistribution layer 141 to the upper guard line 130 on the surface 4000S of the interlayer insulation layer 4000. Accordingly, the upper guard line 130 may receive the ground voltage provided from the ground pad 110. That is, the upper guard line 130 may maintain a ground state within the semiconductor chip E. Referring to FIG. 4, the upper guard line 130 may be disposed spaced apart from the operation voltage pad 120 and the second redistribution layer 142 of the chip region 10 on the surface 4000S of the interlayer insulation layer 4000.

Referring to FIGS. 2 to 4, the scribe lane region 30 may be disposed outside the chip sealing region 20. In an embodiment, as illustrated in FIGS. 3 and 4, a test pattern structure 3100 may be disposed in the scribe lane region 30. The test pattern structure 3100 may include, for example, a plurality of conductive patterns z1, z2, z3, z4, and z5. The plurality of conductive patterns z1, z2, z3, z4, and z5 may constitute various electrical test circuits or process monitoring patterns.

As described above, according to an embodiment of the present disclosure, the semiconductor chip E may include the chip guard structure 2100 and the upper guard line 130 that are disposed in the chip sealing region 20 and protect the chip region 10 from external moisture. The upper guard line 130 may be disposed over the chip guard structure 2100. The upper guard line 130 may be disposed spaced apart from the chip guard structure 2100 in a direction perpendicular or substantially perpendicular to the top surface 1001S of the substrate 1001. The chip guard structure 2100 may be connected to the ground well 1001W of the substrate 1001 to maintain a ground state, and the upper guard line 130 may be connected to the ground voltage supply line Va disposed in the chip region 10 to maintain the ground state. A conductive connection means connecting the chip guard structure 2100 to the upper guard line 130 may not be disposed in the interlayer insulation layer 4000 between the chip guard structure 2100 and the upper guard line 130.

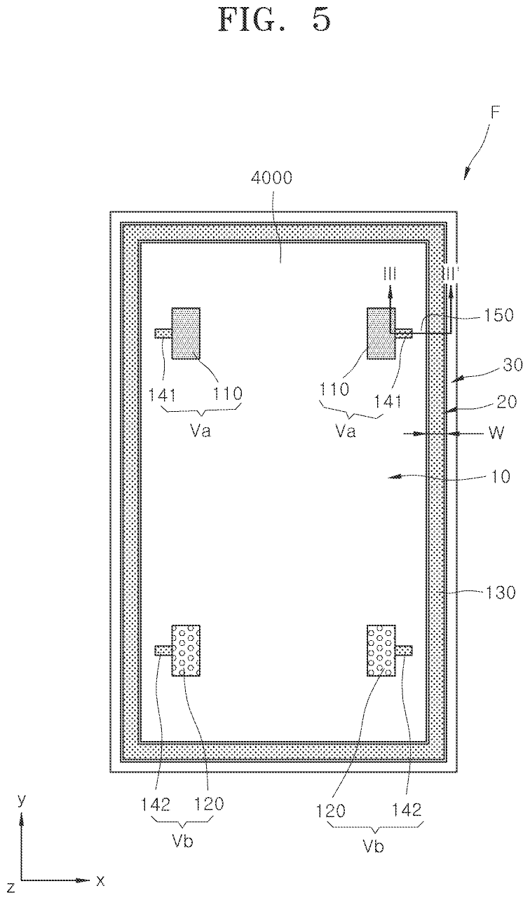

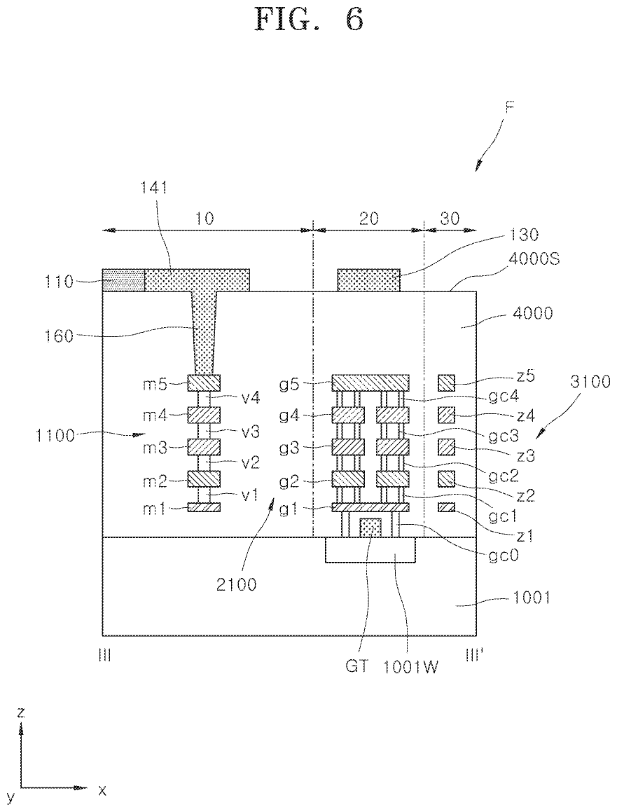

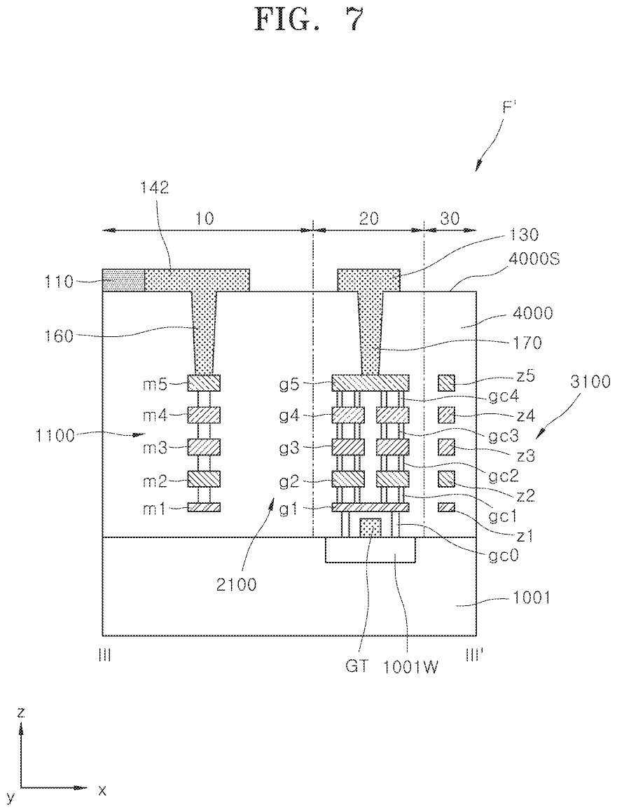

FIG. 5 is a plan view schematically illustrating a semiconductor chip F according to a first comparative example of the present disclosure. FIG. 6 is a cross-sectional view of the semiconductor chip F illustrated in FIG. 5 taken along a line III-III′. FIG. 7 is a cross-sectional view illustrating a semiconductor chip F′ according to a second comparative example of the present disclosure. The semiconductor chip F′ of FIG. 7 is a modified example of the semiconductor chip F illustrated in FIGS. 5 and 6.

Referring to FIGS. 5 and 6, the semiconductor chip F includes a chip guard structure 2100 and an upper guard line 130 that protect a chip region 10 from external moisture. The upper guard line 130 of the semiconductor chip F is not electrically connected to a ground voltage supply line Va or an operation voltage supply line Vb. In addition, the upper guard line 130 is not electrically connected to the chip guard structure 2100 that maintains an electrical ground state. Accordingly, the upper guard line 130 of the semiconductor chip F may maintain an electrical floating state within the semiconductor chip F. However, when the upper guard line 130, which is a barrier structure surrounding the chip region 10, maintains the electrical floating state, the upper guard line 130 may be electrically unstable. When an overvoltage or overcurrent is supplied to the upper guard line 130, the upper guard line 130 may be vulnerable to electrical destruction caused by the overvoltage or overcurrent. That is, unlike the chip guard structure 2100, which maintains the ground state, the upper guard line 130, which maintains the electrical floating state, may be vulnerable to the electrical destruction phenomenon. Accordingly, the semiconductor chip F may have reduced electrical stability compared to the semiconductor chip E of FIGS. 2 to 4.

Compared to the semiconductor chip F of FIGS. 5 and 6, in the semiconductor chip F′ of FIG. 7, the upper guard line 130 is electrically connected to the chip guard structure 2100 through a chip guard connection contact 170. Accordingly, the upper guard line 130 is electrically connected to a ground well 1001W to maintain an electrical ground state. However, compared to the semiconductor chip E, which is an embodiment of the present disclosure, the upper guard line 130 of the semiconductor chip F′ may be electrically open with respect to the ground voltage supply line (e.g., Va in FIG. 5) of the chip region 10.

The chip guard connection contact 170 is disposed between the chip guard structure 2100 and the upper guard line 130 in the chip sealing region 20, and is disposed in a fence shape surrounding the chip region 10. However, since the chip guard connection contact 170 is disposed directly over the chip guard structure 2100, the chip guard connection contact 17 may apply stress to the chip guard structure 2100. Due to the applied stress, a delamination and cracking phenomenon may occur in the interlayer insulation layer 4000 adjacent to the chip guard structure 2100. In addition, when subsequent heat treatment is performed, a defect may occur in which the metal pattern layer located adjacent to the region where the delamination phenomenon and crack phenomenon occurred is locally melted.

As described above, the semiconductor chip F′ of FIG. 7 may prevent the upper guard line 130 from being floated and becoming electrically unstable, compared to the semiconductor chip F of FIG. 6, but structural defects may occur in the chip sealing region 20 of the semiconductor chip F′ in FIG. 7 due to the stress applied downward by the chip guard connection contact 170.

On the other hand, according to an embodiment of the present disclosure, the upper guard line 130 of the semiconductor chip E may be electrically connected to the ground voltage supply line Va of the chip region 10 while being spaced apart from the chip guard structure 2100. Accordingly, the electrical stability of the upper guard line 130 may be improved in the chip sealing region 20 compared to the semiconductor chip F of FIG. 6, and the structural stability of the chip guard structure 2100 may be improved in the chip sealing region 20 compared to the semiconductor chip F′ of FIG. 7.

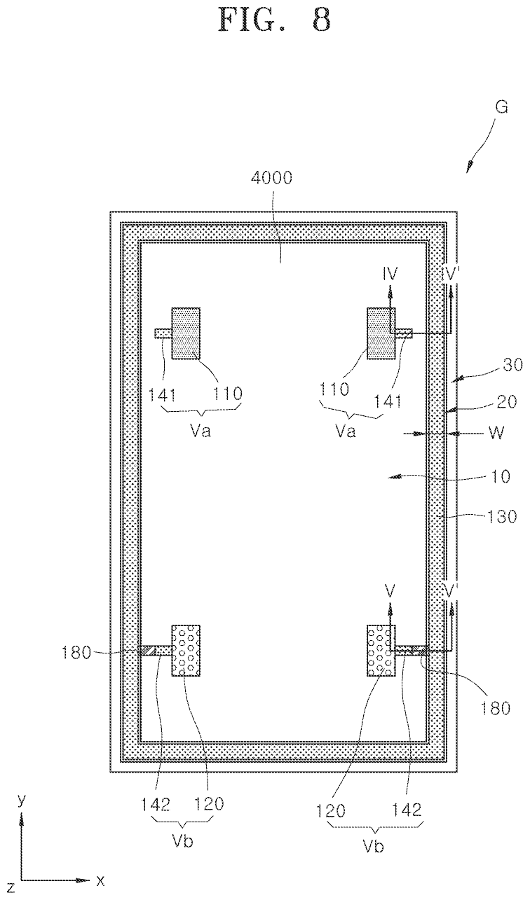

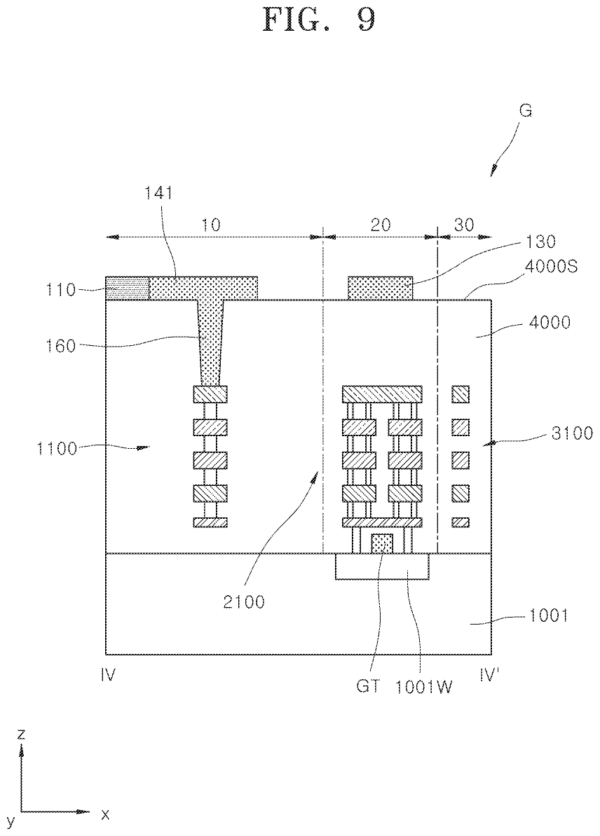

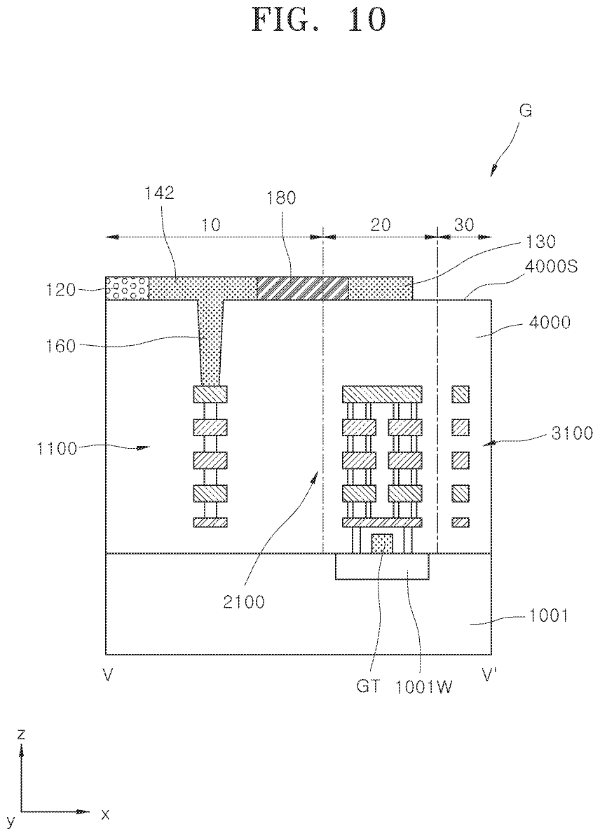

FIG. 8 is a plan view schematically illustrating a semiconductor chip G according to another embodiment of the present disclosure. FIG. 9 is a cross-sectional view of the semiconductor chip G illustrated in FIG. 8 taken along a line IV-IV′. FIG. 10 is a cross-sectional view of the semiconductor chip G illustrated in FIG. 8 taken along a line V-V′. The semiconductor chip G may correspond to one of the plurality of semiconductor chips A, B, C, and D described above with reference to FIG. 1.

Referring to FIGS. 8 to 10, the semiconductor chip G may be differentiated from the semiconductor chip E of FIGS. 2 to 4 in that the semiconductor chip G has an upper guard line 130 electrically connected to an operation voltage supply line Vb. The operation voltage provided by the operation voltage supply line Vb is applied to drive or operate the semiconductor chip G and may include a voltage greater than 0 V. For example, the upper guard line 130 may be electrically insulated from ground voltage supply line Va.

Referring now to FIGS. 8 to 10, the upper guard line 130 may be connected to a second redistribution layer 142 through a conductive connection pattern 180. As the second redistribution layer 142 is connected to the operation voltage pad 120, the upper guard line 130 may maintain the operation voltage provided by the operation voltage supply line Vb. The conductive connection pattern 180 may be disposed across a chip region 10 and a chip sealing region 20 on an interlayer insulating layer 4000.

As described above, the upper guard line 130 may be disposed spaced apart from a chip guard structure 2100 disposed below the upper guard line 130, and a conductive connection means connecting the upper guard line 130 to the chip guard structure 2100 may not be disposed. The upper guard line 130 may escape the electrical floating state by maintaining the operation voltage provided through the operation voltage supply line Vb. As a result, in the semiconductor chip G, the electrical stability of the upper guard line 130 and the structural stability of the chip guard structure 2100 may be improved together.

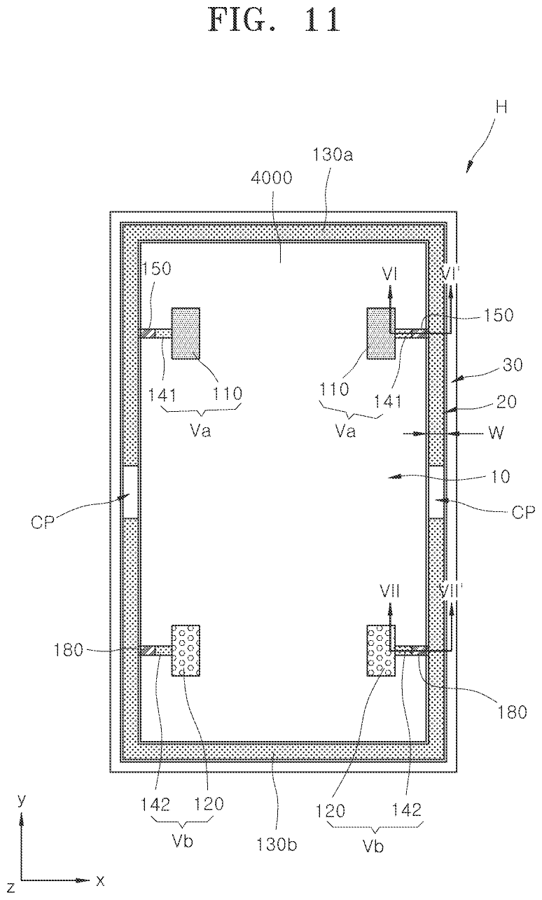

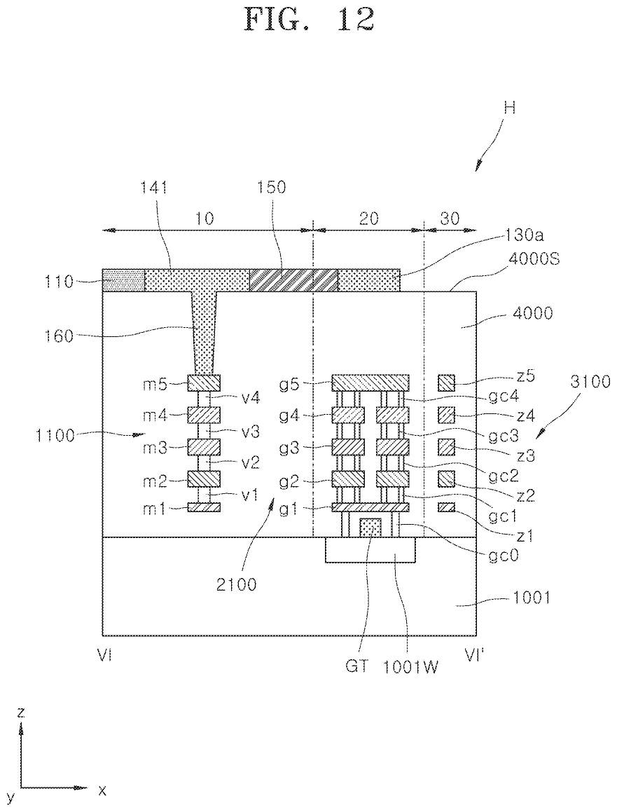

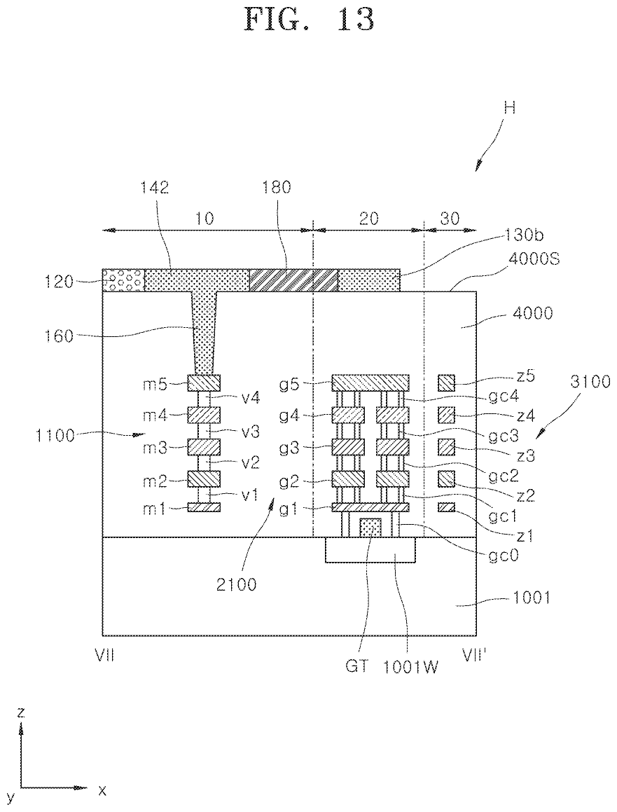

FIG. 11 is a plan view schematically illustrating a semiconductor chip H according to another embodiment of the present disclosure. FIG. 12 is a cross-sectional view of the semiconductor chip H illustrated in FIG. 11 taken along a line VI-VI′. FIG. 13 is a cross-sectional view of the semiconductor chip H illustrated in FIG. 11 taken along a line VII-VII′. The semiconductor chip H may correspond to one of the plurality of semiconductor chips A, B, C, and D described above with reference to FIG. 1.

Referring to FIGS. 11 to 13, the semiconductor chip H may be differentiated from the semiconductor chip E of FIGS. 2 to 4 in that the semiconductor chip H has an upper guard line 130 electrically connected to voltage supply lines Va and Vb, respectively.

Referring to FIG. 11, the upper guard line 130 may include first and second upper guard layers 130a and 130b separated from each other. That is, in the upper guard line 130 disposed along the periphery of the chip region 10, a disconnected portion CP where the first upper guard layer 130a and the second upper guard layer 130b are disconnected from each other may occur. An interlayer insulation layer 4000 may be disposed in the disconnected portion CP. Accordingly, the first upper guard layer 130a and the second upper guard layer 130b may be electrically insulated from each other.

Referring to FIGS. 11 to 13, the first upper guard layer 130a may be electrically connected to the ground voltage supply line Va by a first conductive connection pattern 150 formed on a surface 4000S of the interlayer insulation layer 4000. The first conductive connection pattern 150 may connect the first upper guard layer 130a to a first redistribution layer 141. As the first redistribution layer 141 is connected to a ground pad 110, the first upper guard layer 130a may receive a ground voltage. Moreover, the second upper guard layer 130b may be electrically connected to the operation voltage supply line Vb by a second conductive connection pattern 180 on the surface 4000S of the interlayer insulation layer 4000. The second conductive connection pattern 180 may connect the second upper guard layer 130b to a second redistribution layer 142. As the second redistribution layer 142 is connected to an operation voltage pad 120, the second upper guard layer 130b may receive an operation voltage.

Referring to FIGS. 12 and 13, the first and second upper guard layers 130a and 130b may be spaced apart from a chip guard structure 2100 disposed below the first and second upper guard layers 130a and 130b. Also, conductive connection means connecting the first and second upper guard layers 130a and 130b to the chip guard structure 2100 may not be formed. In addition, the first upper guard layer 130a may maintain the ground voltage through the ground voltage supply line Va while the second upper guard layer 130b may maintain the operation voltage through the operation voltage supply line Vb. As a result, in the semiconductor chip H, the electrical stability of the first and second upper guard layers 130a and 130b and the structural stability of the chip guard structure 2100 may be improved.

The technical concepts of the present invention have been disclosed in conjunction with some embodiments as described above. Those skilled in the art will appreciate that various modifications, additions, and substitutions are possible, without departing from the scope of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts. Furthermore, the embodiments may be combined to form additional embodiments.

What is claimed is:

1. A semiconductor chip comprising:
a chip region and a chip sealing region disposed in a substrate,;
a circuit pattern structure disposed in the chip region;
a chip guard structure disposed in the chip sealing region and surrounding the chip region;
a voltage supply line disposed over the circuit pattern structure in the chip region and supplying a predetermined voltage to the circuit pattern structure; and
an upper guard line disposed over the chip guard structure in the chip sealing region and electrically connected to the voltage supply line.

2. The semiconductor chip of claim 1, wherein the upper guard line is disposed to surround the chip region.

3. The semiconductor chip of claim 1, further comprising a conductive connection pattern connecting the voltage supply line to the upper guard line.

4. The semiconductor chip of claim 1, wherein the voltage supply line and the upper guard line are located on substantially the same plane over the substrate.

5. The semiconductor chip of claim 1, wherein the voltage supply line and the upper guard line include substantially the same material.

6. The semiconductor chip of claim 1,
wherein the chip guard structure is disposed to surround the chip region, and
wherein the upper guard line is disposed to overlap the chip guard structure in a direction perpendicular or substantially perpendicular to a surface of the substrate.

7. The semiconductor chip of claim 1, wherein the upper guard line is physically separated from the chip guard structure.

8. The semiconductor chip of claim 1, wherein the voltage supply line includes:
a power pad receiving the predetermined voltage from an external device; and
a redistribution layer extending from the power pad.

9. The semiconductor chip of claim 8, wherein the power pad includes a ground pad or an operation voltage pad.

10. The semiconductor chip of claim 1, wherein the voltage supply line includes:
a ground pad receiving a ground voltage from an external device;
an operation voltage pad receiving an operation voltage from the external device;
a first redistribution layer extending from the ground pad; and
a second redistribution layer extending from the operation voltage pad.

11. The semiconductor chip of claim 10,
wherein the upper guard line includes a first upper guard layer and a second upper guard layer that are separated from each other,
wherein the first upper guard layer is electrically connected to the first redistribution layer, and
wherein the second upper guard layer is electrically connected to the second redistribution layer.

12. The semiconductor chip of claim 11, further comprising:
a first conductive connection pattern connecting the first upper guard layer and the first redistribution layer to each other; and
a second conductive connection pattern connecting the second upper guard layer and the second redistribution layer to each other.

13. The semiconductor chip of claim 1, wherein the chip guard structure includes:
at least two guard metal layers disposed over a surface of the substrate spaced apart from each other in a direction perpendicular or substantially perpendicular to the surface of the substrate;
an intermetal contact layer connecting the at least two guard metal layers to each other; and
a lower contact layer connecting a lowest guard metal layer among the at least two guard metal layers and a ground well of the substrate to each other.

14. A semiconductor chip comprising:
a substrate including a chip region and a chip sealing region located outside the chip region;
a chip guard structure disposed in the chip sealing region to surround the chip region;
a voltage supply line disposed in the chip region; and
an upper guard line disposed in the chip sealing region spaced apart from the chip guard structure over the substrate, the upper guard line electrically insulated from the chip guard structure, and electrically connected to the voltage supply line.

15. The semiconductor chip of claim 14, wherein the voltage supply line and the upper guard line are located on substantially the same plane over the substrate.

16. The semiconductor chip of claim 15, further comprising a conductive connection pattern connecting the voltage supply line to the upper guard line.

17. The semiconductor chip of claim 14, further comprising a circuit pattern structure disposed in the chip region to receive a predetermined voltage from the voltage supply line.

18. The semiconductor chip of claim 14, wherein the upper guard line is disposed to overlap the chip guard structure in a direction perpendicular or substantially perpendicular to a surface of the substrate.

19. The semiconductor chip of claim 14, wherein the voltage supply line includes:
a power pad receiving the predetermined voltage from an external device; and
a redistribution layer extending from the power pad.

20. The semiconductor chip of claim 19, wherein the power pad includes a ground pad or an operation voltage pad.
